(19) United States
(12) Patent Application Publication
(10) Pub. No.: US 2012/0003389 A1
(43) Pub. Date: Jan. 5, 2012

(54) MOCVD REACTOR HAVING A CEILING PANEL COUPLED LOCALLY DIFFERENTLY TO A HEAT DISSIPATION MEMBER

(76) Inventors: Daniel Brien, Aachen (DE); Roland Püsche, Aachen (DE); Walter Franken, Eschwiler (DE)

(21) Appl. No.: 13/256,224

(22) PCT Filed: Mar. 10, 2010
(86) PCT No.: PCT/EP2010/053015

§ 371 Date: Sep. 12, 2011

(30) Foreign Application Priority Data
Mar. 16, 2009 (DE) 10 2009 003624.5
Feb. 25, 2010 (DE) 10 2010 000 554.1

(51) Int. Cl. C23C 16/46; C23C 16/458; C23C 16/455

(52) U.S. Cl. 427/255.23; 118/725

(57) ABSTRACT

The invention relates to a device for depositing at least one, in particular crystalline, layer on at least one substrate (5), having a susceptor (2) for accommodating the at least one substrate (5), the susceptor forming the floor of a process chamber (1), having a cover plate (3) which forms the ceiling of the process chamber (1), and having a gas inlet element (4) for introducing process gases, which decompose into the layer-forming components in the process chamber as the result of heat input, and a carrier gas, wherein below the susceptor (2) a multiplicity of heating zones (H₁-H₈) are situated next to one another, by means of which in particular different heat outputs (Q₁, Q₂) are introduced into the susceptor (2) in order to heat the susceptor surface facing the process chamber (1) and the gas located inside the process chamber (1), a heat dissipation element (8) which is thermally coupled to the cover plate (3) being provided above the cover plate (3) in order to dissipate the heat transported from the susceptor (2) to the cover plate (3). To increase the crystal quality and the efficiency of the deposition process, it is proposed that the heat-conveying coupling between the cover plate (3) and the heat dissipation element (8) is different at different locations, heat-conveying coupling zones (Z₁-Z₈) having high heat-conveying capability corresponding in location to heating zones (H₁-H₈) of high heat output (Q₁, Q₂).

The invention relates to a device for depositing at least one, in particular crystalline, layer on at least one substrate, having a susceptor for accommodating the at least one substrate, the susceptor forming the floor of a process chamber, having a cover plate which forms the ceiling of the process chamber, and having a gas inlet element for introducing process gases, which decompose into the layer-forming components in the process chamber as the result of heat input, and a carrier gas, wherein below the susceptor a multiplicity of heating zones are situated next to one another, by means of which heat outputs are introduced into the susceptor in order to heat the susceptor surface facing the process chamber and the gas located inside the process chamber, a heat dissipation element which is thermally coupled to the cover plate being provided above the cover plate in order to dissipate the heat transported from the susceptor to the cover plate.

The invention further relates to the use of such a device for carrying out a coating process.

U.S. Pat. No. 4,961,399 A describes a device for depositing layers of Group III-V compounds on a multiplicity of substrates situated on a susceptor around a center of a rotationally symmetrical process chamber. A gas inlet element is situated in the center of the process chamber for introducing at least one hydride, for example NH₃, AsH₃, or PH₃. Organometallic compounds, for example TMGa, TMIn, or TMAl, are also introduced into the process chamber via the gas inlet element. A carrier gas, for example hydrogen or nitrogen, is also introduced into the process chamber together with these process gases. The susceptor is heated from below. This is achieved by thermal radiation or high-frequency coupling. Reference is made to DE 102 47 921 A1 with regard to the arrangement of such a heater vertically beneath the susceptor. The process chamber extends in the horizontal direction, and is delimited from above by a cover plate. U.S. Pat. No. 4,961,399 describes a cover plate made of quartz, which via a horizontal gap is spaced from a reactor cover. DE 100 43 599 A1 describes a cover plate which is composed of a plurality of ring-shaped elements that extend beneath a solid plate.

DE 10 2004 009 130 A1 describes an MOCVD reactor having a process chamber situated symmetrically around a central gas inlet element, the gas inlet element forming inlet gas zones situated vertically above one another. A Group III component is introduced into the process chamber through the middle zone, and a hydride as the Group V component is introduced into the process chamber through the two outer gas inlet zones.

The horizontal temperature profile inside the process chamber is a function, inter alia, of the local heat output of the heater, i.e., the local heat transfer rate. The heater is divided into different heating zones situated horizontally next to one another in the direction of flow of the process gas in the process chamber. For a rotationally symmetrical process chamber, the heating zones are arranged in a spiral manner around the center. Each heating zone has its own individual heat output, so that different quantities of energy per unit time are introduced into the susceptor at different locations. The upward dissipation of energy occurs via thermal radiation or transfer of heat from the surface of the susceptor facing the process chamber toward the ceiling of the process chamber, i.e., the cover plate. The solid plate, i.e., reactor wall, situated to the rear of the cover plate is used as a heat dissipation element.

Undesired homogeneous gaseous phase reactions may occur between the various process gases when layers of Group III-V compounds are deposited using the MOCVD process. When the two process gases NH₃ and TMGa, for example, are mixed together, by-products with NH₃ may form during the decomposition of TMGa in the presence of NH₃, this being referred to as adduct formation. This adduct formation may occur up to the final/highest partial decomposition temperature of the organometallic; TMGa, for example, decomposes at 100° C., first into DMGa, and then into Ga only after decomposition via MMGa at approximately 500° C. The intermediate products which result in the course of this partial decomposition react with the hydride. The resulting chemical compounds may agglomerate in the gaseous phase to form clusters, which is referred to as nucleation. These two phenomena are known in principle, but not the precise sequences and relationships of these chemical substances in a defined geometry during the MOCVD. This parasitic behavior of the gaseous phase is considered to be responsible for the quality of the crystal growth and the limitation of the growth rate and the conversion efficiency of the very expensive precursors. In addition, thermophoresis transports the resulting particles in the direction opposite to the temperature gradient, toward the cover plate which forms the process chamber, whereupon the particles easily fall downward, greatly reducing the yield and impairing the quality of the crystal.

However, increasing the crystal quality of the deposited layers requires that the process be carried out at total pressures of 600 mbar and higher in order to improve the effective Group V excess at the growth surface.

Therefore, an internal study was conducted to investigate the important relationships between process pressure, which determines the free path length between the reactants, the propagation time of the gas mixture in the process chamber, which determines the probability of reaction, and the concentration of the reactants, which determines the abundance of the reaction, and to analyze the isothermal distribution in the process chamber.

One significant finding is that the quantity of parasitic losses may be greatly reduced when the temperature of the cover plate which forms the process chamber is set higher than 500° C. It is particularly important that the radial temperature distribution is very homogeneous. Gradients which occur in the designs up to now prevent positive results at an elevated temperature of the cover plate. The other significant finding is that the properties of the parasitic covering on the cover plate which forms the process chamber change from a loose powder to a strong, thin film.

To ensure the advantageous properties using the cover plate which forms the process chamber, the thermal management must include an adjustable homogeneous temperature distribution.

DE 10043599 A1 describes an additional heater which allows heating also of the process chamber ceiling. If such a heater is dispensed with and the cover plate is heated only by the thermal transport from the susceptor, the local temperatures in the cover plate differ from one another significantly. These temperature gradients result in mechanical load on the cover plate, and there is a risk that the cover plate may fracture after a certain number of heating cycles. The high temperature gradient may also cause deformation of the cover plate. For process chamber diameters of 600 mm and greater, and for high total pressure values of up to 1000 mbar in the process chamber, these deformations adversely affect the layer growth.

The growth on the substrates takes place at a substrate temperature, i.e., a gaseous phase temperature directly beneath the substrate, at which the growth is kinetically limited. The temperature is selected in such a way that all reactants which reach the substrate via a diffusion process through the boundary layer have sufficient time on the substrate surface to find their most favorable thermodynamic position while forming a monocrystal. Thus, the growth temperature is above the temperature at which the deposition process is controlled by diffusion.

It is an object of the invention, therefore, to provide measures by means of which a device of the generic kind may be refined to increase crystal quality and the efficiency of the deposition processes carried out therein.

The object is achieved by the invention set forth in the claims, the subsidiary claims representing not only advantageous refinements of the claims to which they are subordinated, but also independent achievements of the object.

It is first and primarily provided that the heat-conveying coupling between the cover plate and the heat dissipation element is locally different. The regions having high heat-conveying capacity may thus be associated as to location with the heating zones in which a high heat output is coupled into the susceptor. As a result, the cover plate is heated only by heat which is supplied by the susceptor. At locations where a large quantity of heat per unit time is transported to the cover plate, a large quantity of heat per unit time is also transported away due to the high thermal conductivity. At locations where the quantity of heat transported to the cover plate per unit time is less, a correspondingly smaller quantity of heat is transported away. As a result, the temperature differences at various locations in the cover plate, i.e., the horizontal temperature gradients, are smaller than in the prior art. The heat-conveying coupling zones are preferably formed by a horizontal gap between the cover plate and the heat dissipation element. In order for these heat-conveying zones to have locally different heat-conveying capabilities, the gap height has locally different values. The gap height of each heat-conveying coupling zone is a function of the heat output of the heating zone associated with the particular heat-conveying coupling zone. The mutually associated heat-conveying coupling zones and heating zones are vertically situated one directly one above the other. If the heating zones are annularly arranged around the center, the heat-conveying coupling zones are also annularly arranged around the center. The heating zones adjacent to the gas inlet element usually supply a lower heat output than the heating zones situated in the region beneath the substrate. However, it is not just the heating zones associated with the gas inlet zone that operate with reduced heat output. The heating zones which are remotely situated from the gas inlet element and which are adjacent to a gas outlet element also operate with reduced heat output. As a result, the gap height of the horizontal gap between the cover plate and the heat dissipation element is larger in the region of the gas inlet zone and in the region of the gas outlet zone than in the region of the growth zone situated therebetween, in which the substrates are situated. The lower surface of the heat dissipation element which delimits the horizontal gap may have a cross section which extends on a stepped or curved contour line. The gap height of the horizontal gap then changes in a step-like or continuous manner in the direction of flow of the process gas. The lower gap wall of the horizontal gap is formed by the upwardly facing surface of the cover plate, which may extend flatly. The device according to the invention preferably has a design that is substantially rotationally symmetrical, the axis of symmetry extending vertically through the center of the gas inlet element, which may have a configuration according to DE 10 2004 009 130 A1. A lower end face of the gas inlet element may lie in a central recess in the susceptor, so that process gas flowing from an inlet zone, situated directly above the susceptor surface, is able to flow into the process chamber in a trouble-free manner. This process gas is preferably a hydride, for example NH₃, which together with a carrier gas is introduced at that location. Located above this inlet zone is another inlet zone for introducing the organometallic component, which may be TMAl. A third inlet zone, through which once again the hydride is introduced into the process chamber, is located directly beneath the cover plate. The inlet zones are connected to feed lines. The hydride feed lines are connected to associated gas metering devices of a gas supply system. The MO feed lines are likewise connected to metering devices of a gas supply system. All feed lines are individually purgeable with a carrier gas, i.e., are connected to a carrier gas feed line. A carrier gas also preferably flows through the horizontal gap. The carrier gas may be hydrogen, nitrogen, or an inert gas, or a mixture of these gases. The heat-conveying capacity within the horizontal gap may be adjusted using the mixture of these gases. As a result of these measures, the difference between the maximum temperature and the minimum temperature within the cover plate may be limited to ranges below 100° C., preferably even below 50° C. The cover plate may be made of graphite or quartz in a one-piece design. For a circularly symmetrical process chamber, the cover plate has the shape of a circular disk. In a refinement of the invention, the cover plate may have an increasing material thickness in the direction of flow. The side wall of the cover plate facing the gap then extends in a plane. The wall of the cover plate facing the process chamber extends in cross section at an angle to the wall of the susceptor facing the process chamber, so that the height of the process chamber decreases in the direction of flow.

The invention further relates to use of the previously described device in a deposition process. In this deposition process, various process gases are led into the process chamber through the inlet zones. An organometallic compound, for example TMGa, TMIn, or TMAl, together with a carrier gas, is introduced into the process chamber through the inlet zone located in the center in the vertical direction. A hydride together with a carrier gas is brought into the process chamber through both the upper and lower inlet zones. The hydride may be NH₃, AsH₃, or PH₃. The hydride flows and the MO flow are individually adjustable. The latter also applies for the purge gas flow through the horizontal gap. A substrate is placed on a substrate holder, which is preferably rotatably situated on the susceptor. A plurality of substrate holders may also be annularly arranged around the center of the susceptor, each substrate holder floating individually on a gas cushion and being rotationally driven by the gas flow which produces the gas cushion. In addition, the susceptor as such may be rotationally driven about the center of symmetry of the process chamber. The heaters situated beneath the susceptor may be formed by resistance heaters or RF heaters. The heaters form heating zones which are horizontally adjacent in the direction of flow. In a rotationally symmetrical arrangement, the heating zones annularly surround one another. The heating zones may also surround the center of the process chamber in a spiral manner. According to the invention, the heating zones are supplied with energy in such a way that their heat outputs are adapted to the heat dissipation properties of the heat-conveying coupling zones situated vertically above same, so that the maximum difference in temperatures in the cover plate, measured at two arbitrary locations, is 100° C. or 50° C.

The growth on the substrate takes place at temperatures at which the process gases previously decomposed in the gaseous phase, i.e., in particular decomposition products containing Ga or N, diffuse through a diffusion zone to the substrate surface. The growth is not limited by diffusion. Namely, the growth temperature is above the diffusion-controlled temperature range, at a temperature at which the growth rate is kinetically limited. This temperature is a function of the organometallic used as well as of the hydride used.

The substrate temperature may be in a range from 700° C. to 1150° C. By selecting a suitable purge gas through the horizontal gap, the heat dissipation may be adjusted in such a way that the ceiling temperature of the process chamber is in the range between 500° and 800° C.

The temperature of the cover plate is lower than the temperature of the susceptor. As mentioned at the outset, the organometallic components decompose into metal atoms in a stepwise process. Thus, for example, TMGa decomposes into Ga via the decomposition products DMGa and MMGa. The decomposition starts at approximately 100° C. The starting material is completely decomposed at a temperature of approximately 500° C. Between these two temperatures the decomposition products, for example DMGa and MMGa, are in the gaseous phase. Thus, adduct formation, subsequent nucleation, and clustering—which must be avoided—may take place in this temperature range. This temperature range is a function of the organometallic used. The ceiling temperature is selected so that it is above this adduct formation temperature, i.e., is at a temperature at which no intermediate decomposition products are present in the gaseous phase. However, the surface temperature of the cover plate is limited not only from below, but also from above. The temperature of the cover plate should be in a temperature range in which the crystal growth is limited by diffusion. Thus, the temperature lies in a temperature range that is equivalent to the diffusion limitation, and therefore below the susceptor temperature, which is in the kinetically limited temperature range.

Exemplary embodiments of the invention are explained below with reference to accompanying drawings, which show the following:

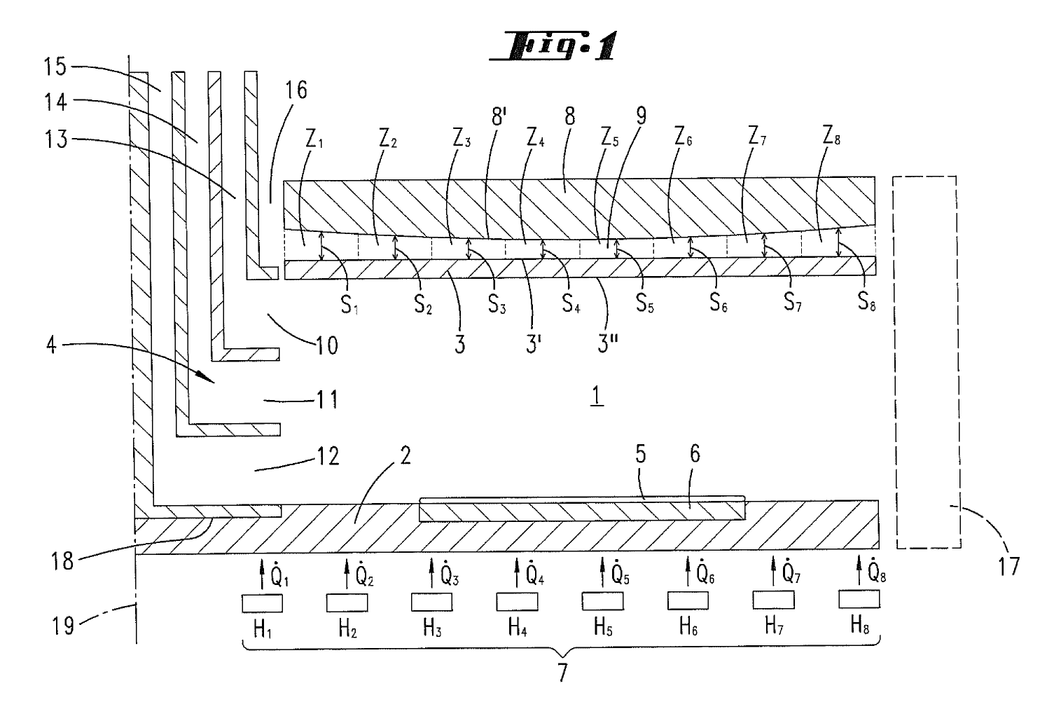

FIG. 1 shows the right side of a cross section through a process chamber of a first exemplary embodiment which is rotationally symmetrical about the axis 19;

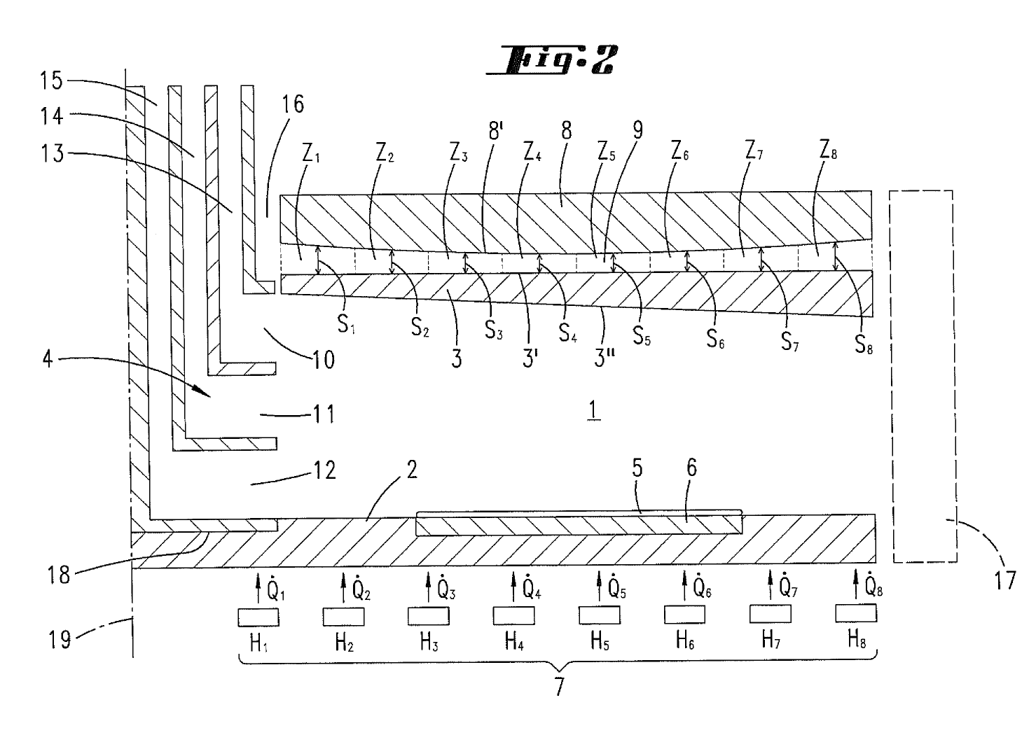

FIG. 2 shows such a cross section of a second exemplary embodiment of the invention;

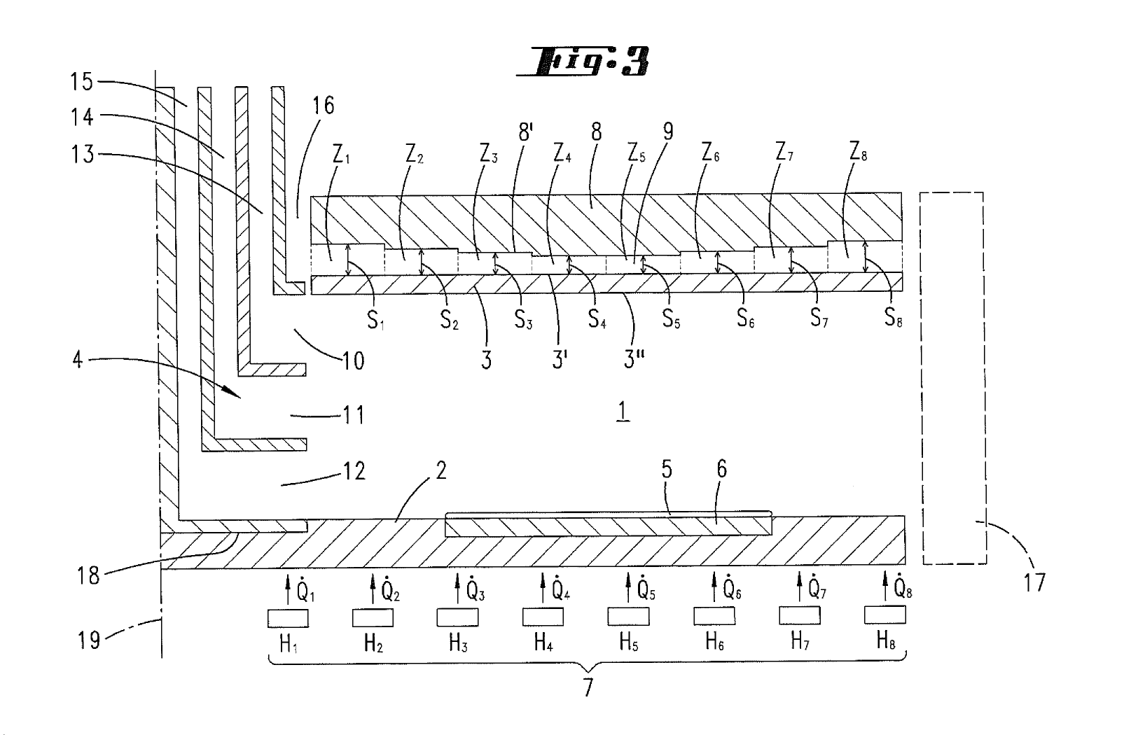

FIG. 3 shows such a cross section of a third exemplary embodiment of the invention;

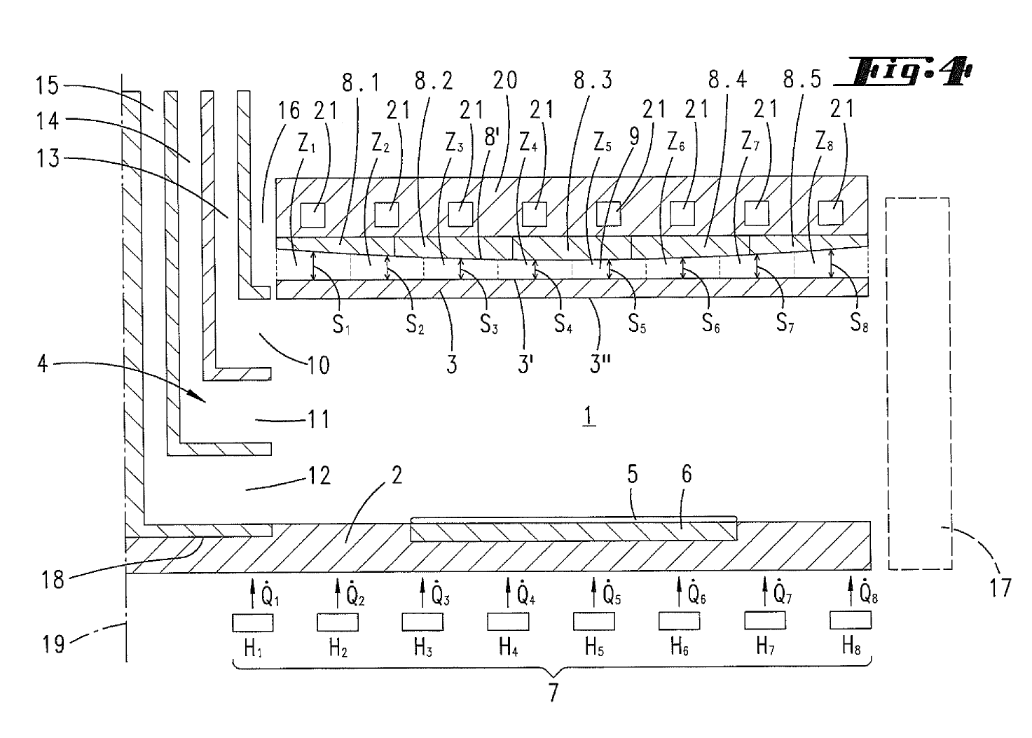

FIG. 4 shows such a cross section of a fourth exemplary embodiment of the invention; and

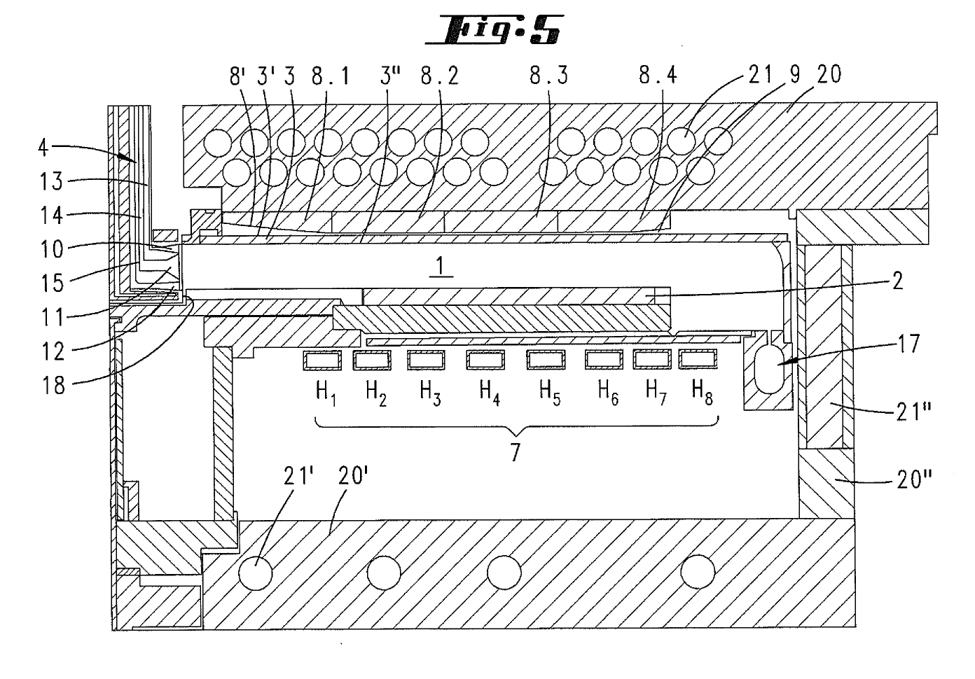

FIG. 5 shows such a cross section of a fifth exemplary embodiment of the invention.

The basic design of an MOCVD reactor of the type to which the invention relates is known from the prior art mentioned at the outset, to which reference in this regard, inter alia, is made.

The MOCVD reactor of the exemplary embodiments has a susceptor 2, which is made of a graphite or quartz plate having a circular disk shape and which may be rotationally driven about a rotational axis 19. The rotational axis 19 is the axis of symmetry of the overall reactor. The gas inlet element 4 extends in the axis of symmetry 19 of the reactor. A lower end face of the gas inlet element 4 lies in a recess 18 in the susceptor 2, so that the inlet zone 12 situated directly above the recess opens into the region of the susceptor 2 near the floor. Above this inlet zone 12, through which a hydride, for example NH₃, AsH₃, or PH₃, is introduced into the process chamber 1, is located a second inlet zone 11, through which an organometallic component, for example TMGa, TMIn, or TMAl, may be introduced into the process chamber 1. A third inlet zone 10 through which one of the above-mentioned hydrides may likewise be introduced into the process chamber 1 directly adjoins a cover plate 3 which delimits the process chamber 1 from above.

The process chamber 1 thus extends annularly in the horizontal direction around the gas inlet element 4, and between the horizontally extending susceptor 2 and the cover plate 3, which is situated at a distance from the susceptor 2 and likewise extends in the horizontal direction.

A heat dissipation element 8 is situated above the cover plate 3. This may be a liquid-cooled solid body. The solid body is secured via suitable mountings to the reactor walls, not illustrated, and has channels in its interior through which a liquid coolant flows.

The heat dissipation element 8, which is made of quartz or of steel, for example, has a convexly curved bottom side 8′. This underside 8′ is situated at a spacing from the flatly extending upper wall 3′ of the cover plate 3, thus forming a horizontal gap 9.

In a region which forms a gas inlet zone that is situated directly adjacent to the gas inlet element 4, the horizontal gap 9 has a gap height S₁, S₂ which continuously decreases with the distance from the gas inlet element 4. The two heat-conveying coupling zones Z₁ and Z₂ associated with the gas inlet zone thus have different heat-conveying properties. Due to its large gap height S₁, the first zone Z₁ has a lower heat-transporting capability than the adjacently situated heat-conveying coupling zone Z₂, which has a gap height S₂ that is smaller than S₁.

Heating zones H₁-H₈ are respectively situated beneath each heat-conveying coupling zone Z₁-Z₈, each of which extends annularly around the gas inlet element 4. The heating zones H₁-H₈ are formed by resistance heaters or RF heating coils. The heating zones H₁-H₈ generate heat outputs \dot{Q}₁-\dot{Q}₈ which are different from one another. The heat outputs \dot{Q}₁ and \dot{Q}₂ which are generated by the heating zones H₁ and H₂, respectively, are smaller than the heat outputs \dot{Q}₃, \dot{Q}₄, \dot{Q}₅, and \dot{Q}₆ which are generated by the middle heating zones H₃, H₄, H₅, and H₆, respectively. These heating zones are located directly beneath the substrates 5 annularly arranged around the rotational axis 19, the substrates 5 each resting on rotationally driven substrate holders 6. The rotary drive of the substrate holders 6 is achieved via gas flows, so that the substrate holders 6 are supported on a gas cushion.

The heat-conveying coupling zones Z₃-Z₆ are located vertically above the heating zones H₃-H₆ respectively associated with these growth zones. The gap heights S₃, S₄, S₅, and S₆ associated with these heat-conveying coupling zones Z₃-Z₆, respectively, are smaller than the gap heights of the heat-conveying coupling zones Z₁ and Z₂, and are smaller than the gap heights S₇ and S₈ of the two radially outermost heat-conveying coupling zones Z₇ and Z₈, respectively.

Heating zones H₇ and H₈, which are situated in a gas outlet zone of the process chamber 1, are associated with the radially outermost heat-conveying coupling zones Z₇ and Z₈, respectively. The gas outlet zone is located in the direction of flow on the far side of the substrates 5. The heat outputs \dot{Q}₇ and \dot{Q}₈ coupled into the susceptor by these heating zones H₇ and H₈, respectively, are less than the heat outputs \dot{Q}₃-\dot{Q}₆ coupled into the susceptor 2 by the middle heating zones H₃-H₆, respectively. The gas outlet zone is surrounded by an annular gas outlet element 17.

In the exemplary embodiments, the individual heating zones H₁-H₈ are spaced apart approximately equidistantly. The same applies for the heat-conveying coupling zones Z₁-Z₈, which likewise have widths that are substantially identical in radial extent. It is essential that a heat-conveying coupling zone Z₁-Z₈ exists which is individually associated with each heating zone H₁, respectively, the gap width S₁-S₈ of the respective heat-conveying coupling zone Z₁-Z₈ being adapted to the heat output \dot{Q}₁-\dot{Q}₈ of the respective heating zone H₁-H₈. The adaptation is effected in such a way that the lateral temperature gradient in the cover plate 3 is minimized, and in particular the maximum temperature difference is approximately 100° C., preferably less, namely, of the order of 50° C.

Basically, within the gas inlet zone and the gas outlet zone a smaller quantity of heat per unit time is introduced into the susceptor than in the growth zone in which the substrates 5 are located. However, the heat output which is coupled into the gas inlet zone may be greater than the heat output which is coupled into the gas outlet zone. In the exemplary embodiments illustrated in FIGS. 1 and 2, the wall 8′ of the heat dissipation element 8 extends along a toroidal surface. The wall 8′ which delimits the horizontal gap 9 from above is therefore convexly curved. The minimum gap height of the horizontal gap 9 is in the radial middle region thereof. The horizontal gap 9 has a maximum gap height at the two radial ends of the horizontal gap 9. Accordingly, the heat-conveying coupling zones have the greatest heat-conveying capability in the middle region, and have the lowest [heat]-conveying capability at the radial edges.

The second exemplary embodiment illustrated in FIG. 2 differs from the first exemplary embodiment solely by virtue of the course of the horizontal gap 9 in the region downstream from approximately the middle of the process chamber 1. At this location the curvature of the wall 8′ is somewhat flatter than in the first exemplary embodiment, so that the gap height of the horizontal gap 9 increases less in the direction of flow. Another important difference is the shape of the annular cover plate 3. Here as well, the cover plate 3 has a one-piece design, and may be made of a single annular quartz or graphite plate. Whereas in the first exemplary embodiment illustrated in FIG. 1, the two broad sides of the cover plate 3 extend parallel to one another and parallel to the top side of the susceptor 2, the wall 3″ of the cover plate 3 facing the process chamber 1 extends, as seen in cross section, at an angle to the wall 3′ which delimits the horizontal gap 9. As a result, the vertical height of the process chamber 1 decreases in the direction of flow.

The exemplary embodiment illustrated in FIG. 3 differs from the exemplary embodiment illustrated in FIG. 1 by virtue of the course of the broadside face 8′ of the heat dissipation element 8 facing the horizontal gap 9. This broad side is provided with steps which extend annularly around the centerline 19, the steps being located at different distances S₁-S₈ from the broadside face 3′ of the cover plate 3.

In the exemplary embodiment illustrated in FIG. 4, the heat dissipation element 8 is composed of a multiplicity of annularly internested elements. However, the heat dissipation element may also have a one-piece design. In this exemplary embodiment, the heat dissipation element 8 is not directly cooled by a liquid cooling medium, but instead is connected to the reactor wall in a heat-transferring manner, for example by being screwed in beneath the reactor wall 20. The reactor wall 20 has cooling channels 21 through which a liquid cooling medium flows in order to cool the reactor wall. The reactor wall is made of aluminum or stainless steel, for example. The heat dissipation element 8, which may be composed of a plurality of subregions 8.1-8.5, is made, for example, of aluminum, graphite, or a material having similarly good thermal conductivity. In this exemplary embodiment, the cover plate 3 is likewise preferably made of graphite, but may also be made of quartz. The cover plate 3 is preferably coated with SiC or TaC. For the process using NH₃ and TMGa, i.e., for depositing GaN, the temperatures of the cover plate are between 450° C. and 800° C. For the process using AsH₃ and PH₃ for depositing GaAs or InP, the temperatures of the cover plate are in the range between 150° C. and 550° C.

In both cases the surface temperature of the cover plate 3 is selected so that it is above the adduct formation temperature. The latter is defined by the temperature at which the organometallic component is completely decomposed; a temperature at which practically no intermediate products are present in the gaseous phase which could react with the hydride in the gaseous phase, such that clustering could result due to a nucleation process. However, the surface temperature of the cover plate is also limited from above. This temperature should not be in the range in which the growth on a substrate is kinetically limited. Rather, the temperature should be in a range in which the growth is diffusion-limited in the presence of a substrate, i.e., as a result of the mass transport of the reactants through the diffusion boundary surface.

The exemplary embodiment illustrated in FIG. 5 substantially corresponds to the exemplary embodiment illustrated in FIG. 4. Here as well, the reactor has a housing made of aluminum, having a housing ceiling 20 and a housing floor 20′ parallel thereto. A tubular housing wall 20″ is located between the housing ceiling 20 and the housing floor 20′. A multiplicity of cooling channels 21 is located in the housing ceiling, through which a cooling medium, for example cooling water, flows. Such cooling channels 21′, 21″ are also located in the housing floor 20′ and in the housing wall 20″, respectively.

A heater 7 formed from a spiral coil and having a total of eight windings extends at a distance above the housing floor 21′. Each individual winding forms a heating zone H₁-H₈ which has an individual power output based on design or also determined by tolerances. If this is a resistance heater, the power output is provided essentially as thermal radiation. If the heater is an RF coil, an alternating electromagnetic field is generated which produces eddy currents in the susceptor 1 situated above the heater 7.

The RF radiation field is inhomogeneous, so that zones result inside the susceptor 1 into which different levels of power are coupled. These zones, which in particular are arranged rotationally symmetrically around the center of the process chamber, are heated to different extents, so that the susceptor 1 has an inhomogeneous temperature profile in the radial direction.

It is provided in particular that in a first gas inlet zone which extends directly around the gas inlet element, the susceptor has a lower surface temperature than in a growth zone adjacent thereto. In the radially outermost zone, which adjoins the growth zone, the susceptor once again has a lower surface temperature.

As described above, the heat dissipation occurs through the cover plate 3 and a gap 9 located between the cover plate 3 and a heat dissipation element 8.

The heat dissipation element 8 is composed overall of four ring elements 8.1, 8.2, 8.3, 8.4 which have the same width but have a different cross-sectional profile, so that the height of the gap 9 varies over the radial distance from the center of the process chamber. The radially innermost ring 8.1 of the heat dissipation element 8 has the greatest slope and has the lowest material thickness. The gap width is largest at this location. The gap width decreases in a wedge-like manner as far as and into the region of the second heat dissipation ring 8.2. Approximately from the center thereof, a region of constant height of the gap 9 which is associated with the growth zone extends over the third heat dissipation ring 8.3 to approximately the middle of the fourth heat dissipation ring 8.4. The fourth heat dissipation ring 8.4 has a broadside face 8′ which rises radially, so that the gap 9 has a gap height which increases with increasing radius. The heat dissipation element 8 is absent in the region of the gas outlet ring 17. The gap has maximum height at this location, and extends between the cover plate 3 and the inner side of the reactor ceiling 20.

In this exemplary embodiment the radial cross-sectional contour of the gap 9 has a convex curvature, which is such that the surface temperature at the underside of the cover plate 3″ increases only slightly in the radial direction, namely, practically linearly, from approximately 500° C. in the region of the gas inlet 4 to approximately 600° C. in the region of the gas outlet 17.

On the other hand, on the surface of the susceptor the temperature increases from approximately 500° C. in the region of the gas inlet to approximately 1000° C. at the start of the growth zone, and remains constant from here at approximately 1000° C. over the growth zone.

All features disclosed are (in themselves) pertinent to the invention. The disclosure content of the associated/accompanying priority documents (copy of the prior application) is also hereby included in full in the disclosure of the application, including for the purpose of incorporating features of these documents in claims of the present application.

### LIST OF REFERENCE NUMERALS/CHARACTERS

1 Process chamber
2 Susceptor
3 Cover plate
4 Gas inlet element
5 Substrate
6 Substrate holder
7 Heater
8 Heat dissipation element
9 Horizontal gap
10 Inlet zone
11 Inlet zone
12 Inlet zone
13 Hydride feed line
14 Gas inlet element
15 Hydride feed line
16 Purge gas inlet
17 Gas outlet element
18 Recess
19 Center/rotational axis/axis of symmetry
20 Reactor wall
21 Cooling channel
H Heater
Z₁ to Z₈ Heat-conveying coupling zones
S₁ to S₈ Gap heights
H₁ to H₈ Heating zones

1. Device for depositing at least one, in particular crystalline, layer on at least one substrate (5), having a susceptor (2) for accommodating the at least one substrate (5), the susceptor forming the floor of a process chamber (1), having a cover plate (3) which forms the ceiling of the process chamber (1), and having a gas inlet element (4) for introducing process gases, which decompose into the layer-forming components in the process chamber as the result of heat input, and a carrier gas, wherein below the susceptor (2) a multiplicity of heating zones (H₁-H₈) are situated next to one another, by means of which in particular different heat outputs (\dot{Q}₁,\dot{Q}₂) are introduced into the susceptor (2) in order to heat the susceptor surface facing the process chamber (1) and the gas located inside the process chamber (1), a heat dissipation element (8) which is thermally coupled to the cover plate (3) being provided above the cover plate (3) in order to dissipate the heat transported from the susceptor (2) to the cover plate (3), characterized in that the heat-conveying coupling between the cover plate (3) and the heat dissipation element (8) is different at different locations.

2. Device according to claim 1 or in particular according thereto, characterized in that the heat-conveying coupling zones (Z₁-Z₈) of high heat-conveying capability correspond in location to heating zones (H₁-H₈) of high heat output (\dot{Q}₁, \dot{Q}₂).

3. Device according to one or more of the preceding claims or in particular according thereto, characterized in that the heat-conveying coupling zones (Z₁-Z₈) are formed by a horizontal gap (9) between the cover plate (3) and the heat dissipation element (8) that has different gap heights (S₁-S₈) at different locations, the gap heights (S₁-S₈) of each heat-conveying coupling zone (Z₁-Z₈) in particular being a function of the heat output (\dot{Q}₁, \dot{Q}₂) of the respective heating zone (H₁) situated vertically beneath the heat-conveying coupling zone (Z₁-Z₈).

4. Device according to one or more of the preceding claims or in particular according thereto, characterized in that gap heights (S₁, S₂) in the region of a gas inlet zone adjacent to the gas inlet element (4) and the gap heights (S₇, S₈) in the region of a gas outlet zone situated remotely from the gas inlet element (4) are greater than the gap heights (S₃-S₆) of a growth zone which is situated between the gas inlet zone and the gas outlet zone and in which the at least one substrate (5) is situated.

5. Device according to one or more of the preceding claims or in particular according thereto, characterized in that the surface of the heat dissipation element (8) facing the cover plate (3) and delimiting the horizontal gap (9) has a stepped or curved, smooth-walled progression.

6. Device according to one or more of the preceding claims or in particular according thereto, characterized in that the horizontal gap (9) adjoins a purge gas inlet (16) to allow a purge gas to flow through the horizontal gap (9).

7. Device according to one or more of the preceding claims or in particular according thereto, characterized by a central symmetrical design of the process chamber, the gas inlet element (4) being situated in the center of symmetry about which the circular cover plate (3) and the circular heat dissipation element (8), which in particular is formed by adjacent rings, are situated.

8. Device according to one or more of the preceding claims or in particular according thereto, characterized in that the gas inlet element (4) is connected to least one hydride feed line (13, 15) and an MO feed line (14), the at least one hydride feed line (13, 15) opening into an inlet zone (10, 12) associated therewith, and the MO feed line (14) opening into an inlet zone (11) associated therewith, the MO inlet zone (11) preferably being vertically adjacent on both sides to an inlet zone (10, 12) for the hydride.

9. Device according to one or more of the preceding claims or in particular according thereto, characterized in that the cover plate (3) is made of graphite or quartz and in particular is produced as one piece.

10. Device according to one or more of the preceding claims or in particular according thereto, characterized in that the vertical height of the process chamber (1) decreases in the direction of flow of the process gas exiting from the gas inlet element (14) in the direction of a gas outlet element (17).

11. Device according to one or more of the preceding claims or in particular according thereto, characterized in that the heater (7) is formed by a multiplicity of heating zones (H₁-H₈) which annularly surround the center (19) of the process chamber (1).

12. Use of a device according to one or more of the preceding claims, characterized in that a layer growth occurs in the device on at least one substrate by introducing process gases into the gas inlet element (4) and by thermal decomposition of the process gases in the process chamber (1) into the layer-forming components, the heat outputs \dot{Q}₁-\dot{Q}₈ of the heating zones (H₁-H₈) being selected in such a way that the maximum difference in temperatures at the cover plate, measured at two arbitrary locations, is 100° C., preferably 50° C.

13. Use of a device according to claim 12 or in particular according thereto, characterized in that the temperature at the cover plate (3) over its entire surface is above the adduct formation temperature of the process gases used, and is below the temperature at which the crystal growth on a substrate is kinetically limited, and in particular for GaN, for example, is in the range between 500° and 800° C., and for GaAs or InP, is between 150° C. and 550° C.

14. Method for depositing at least one, in particular crystalline, layer on at least one substrate (5), featuring a susceptor (2) for accommodating the at least one substrate (5), the susceptor forming the floor of a process chamber (1), featuring a cover plate (3) which forms the ceiling of the process chamber (1), and featuring a gas inlet element (4) for introducing process gases, which decompose into the layer-forming components in the process chamber as the result of heat input, and a carrier gas, wherein below the susceptor (2) a multiplicity of heating zones (H₁-H₈) are situated next to one another, by means of which different heat outputs (\dot{Q}₁, \dot{Q}₂) are introduced into the susceptor (2) in order to heat the susceptor surface facing the process chamber (1) and the gas located inside the process chamber (1), a heat dissipation element (8) which is thermally coupled to the cover plate (3) being provided above the cover plate (3) in order to dissipate the heat transported from the susceptor (2) to the cover plate (3), characterized in that the cover plate (3) on its entire surface facing the process chamber (1) has a temperature that is above the adduct formation temperature of the process gases, but is below a temperature at which the crystal growth on a substrate is kinetically limited.
